(19) United States
(12) Patent Application Publication
(10) Pub. No.: US 2007/0235073 A1
(43) Pub. Date: Oct. 11, 2007

(54) Method of fabricating a thin film photovoltaic cell on a transparent substrate

(76) Inventor: Mario Napolitano, Conneaut Lake, PA (US)

Correspondence Address: Mario Napolitano, P.O. Box 5154, Conneaut Lake, PA, 16316, US

(21) Appl. No.: 11/401,426

(22) Filed: Apr. 10, 2006

(51) Int. Cl. H01L 31/00

(52) U.S. Cl. 136/252

(57) ABSTRACT

The invention is directed to a method of fabricating a Thin Film Photovoltaic Cell that increases the active surface area and improves the electrical contact to the two sides of the active area. Both factors increase the efficiency of the cell.

### RELEVANT PRIOR ART INCLUDES:

| | | |
|---|---|---|
| U.S. Pat. No. 5,797,999 | Aug. 25, 1998 | Sannomiya et al. |
| U.S. Pat. No. 6,337,224 | Jan. 8, 2002 | Okamoto et al. |
| U.S. Pat. No. 6,855,621 | Feb. 15, 2005 | Kondo, et al. |
| U.S. Pat. No. 6,812,499 | Nov. 2, 2004 | Kondo, et al. |
| U.S. Pat. No. 6,802,953 | Oct. 12, 2004 | Sano, et al. |
| U.S. Pat. No. 6,554,973 | Apr. 29, 2003 | Nakayama |
| U.S. Pat. No. 6,399,411 | Jun. 4, 2002 | Hori, et al. |
| U.S. Pat. No. 5,413,959 | May 9, 1995 | Yamamoto, et al. |
| U.S. Pat. No. 6,455,347 | Sep. 24, 2002 | Hiraishi, et al. |

### TECHNICAL FIELD OF THE INVENTION

The invention is directed to method of producing a Thin Film Photovoltaic Cell.

### BACKGROUND OF THE INVENTION

Traditionally, Photovoltaic Solar Cells have been made by using high purity solar-grade silicon wafers, in both single-crystal or multi-crystal wafers. As the world-wide demand for solar cells has enormously increased, a shortage of silicon has become a major problem. Because of this shortage, much research is going into thin film solar cell development. Thin film deposited on inexpensive substrates requires a very small fraction of silicon as compared to solid silicon wafers. Also, films other than silicon are being investigated such as copper indium diselenide (CIS), cadmium telluride (CdTe) and others.

Various methods of manufacturing Thin Film Photovoltaic Cells have been investigated. They fall into two major categories: 1. where the active thin film is deposited on a conductive metal, and 2. where the active film is deposited on a transparent substrate. Even though the first category has a better electrical contact, the trapped sunlight in the thin film is low and thus the cell is less efficient. In the second category, one side of the active film is in contact with a transparent insulator, and thus electrical contact is difficult.

Often a conductive film is interposed between the substrate and the active film. This conductive film interferes with the light passing through to the active layer, and thus reduces efficiency.

### SUMMARY OF THE INVENTION

The object of this invention is to devise a manufacturing technique whereby both sides of the active film (The film may be made of silicon or other photovoltaic compounds.) deposited on a transparent substrate, may be contacted from one side. This would appear as if a flat film is cut and molded into a series of parallel U-shaped segments, and contact is made on the inside and on the outside of the U. By doing this, the problem previously-described in number 2 above, difficult electric contract, is eliminated. At the same time, because of the way the U-shaped segments are made the manufacturing process is simplified.

### FIGURES

1. Starting Material

2. Enlarged View of Starting Material

3. Photovoltaic Film Deposition

4. Fill Trenches with Conductive Material

5. Grind to Expose Side of Photovoltaic Film

6. Selective Etch to Expose Inner Surface of Photovoltaic Film

7. Enlarged View of FIG. 6

8. Fill with Conductive Material

9. Grind Excess Material to Expose Active Junction

10. Deposit Passivation and Antireflective Coating

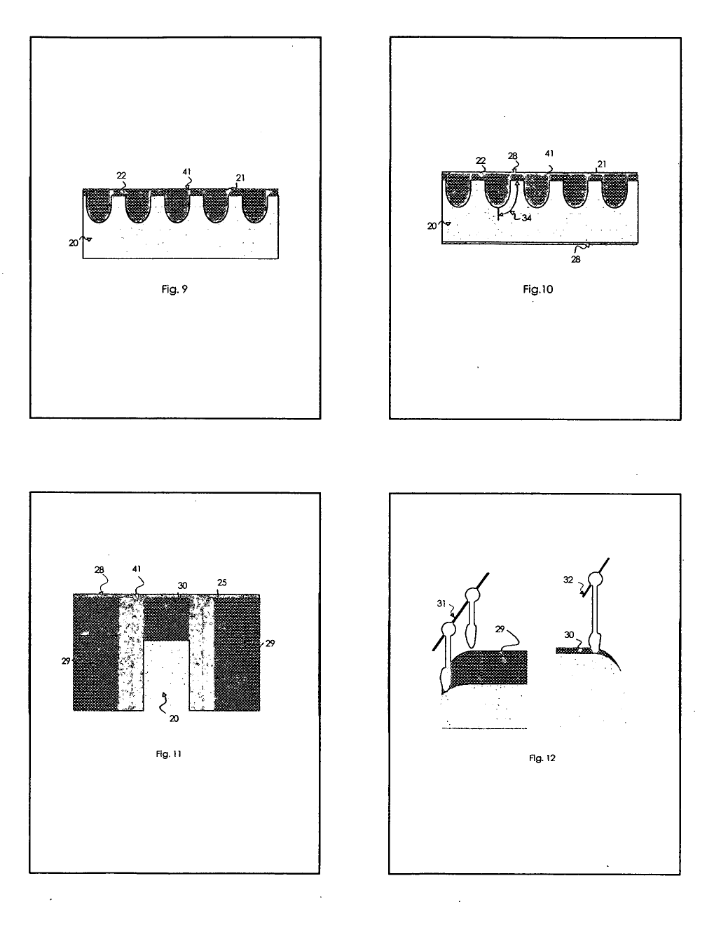

11. Enlarged View of Segment of FIG. 10

12. Attachment of Contact Frame

13. Panel Showing Output and Multiple Light Paths

14. Process Flow

15. Comparison of Active Area Compared to Linear Area

### DETAILED DESCRIPTION OF THE IVVENTION

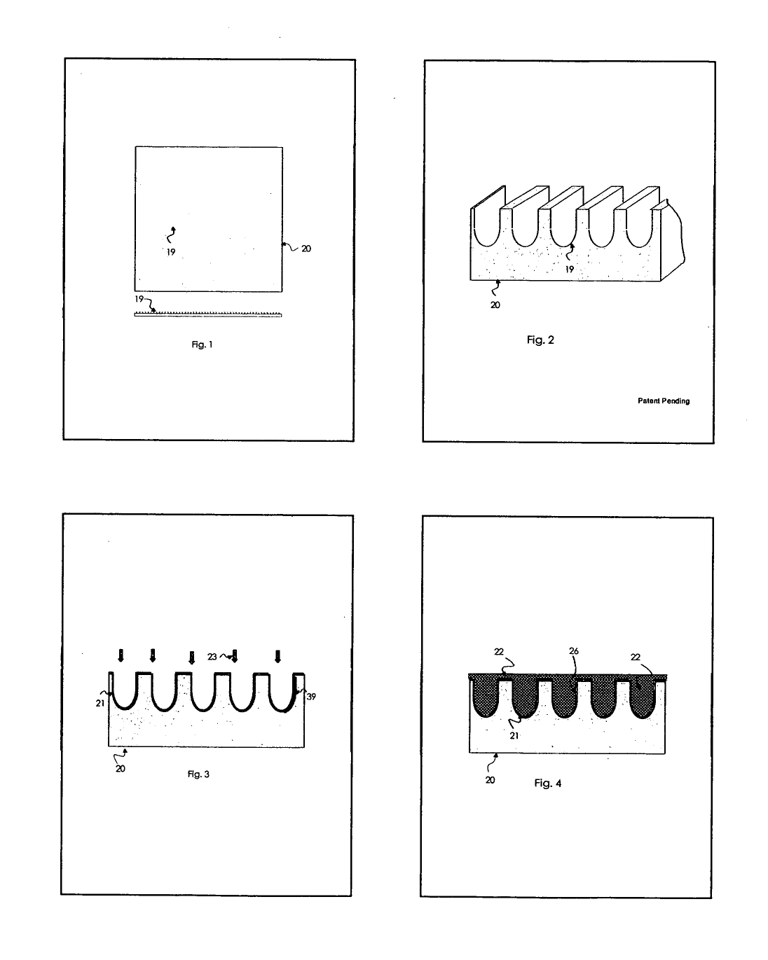

FIGS. 1 and 2 show a transparent plate (20) to be used as a substrate. One entire side is grooved with parallel U-shaped trenches (19). These trenches, when filled with appropriate active material will become the photovoltaic cell. The other side may be flat or contoured to allow sunlight to come in and remain trapped until absorbed. This transparent plate can be manufactured by extrusion, molding, or other technique.

A properly doped film, FIG. 3 (21), is deposited in the trenches by the use of Chemical Vapor Deposition (CVD) or equivalent (23) to form the active junction shown in FIG. 7 (25). Depending on which type of substrate material is used and the impurities it may contain, it may be necessary to deposit a barrier layer (39) prior to the deposition of the active film. The barrier layer prevents the diffusion of impurities into the active film. Also, a barrier layer (39) may be needed in the case of insufficient selectivity in the etch process, which follows later, otherwise the active film would be etched.

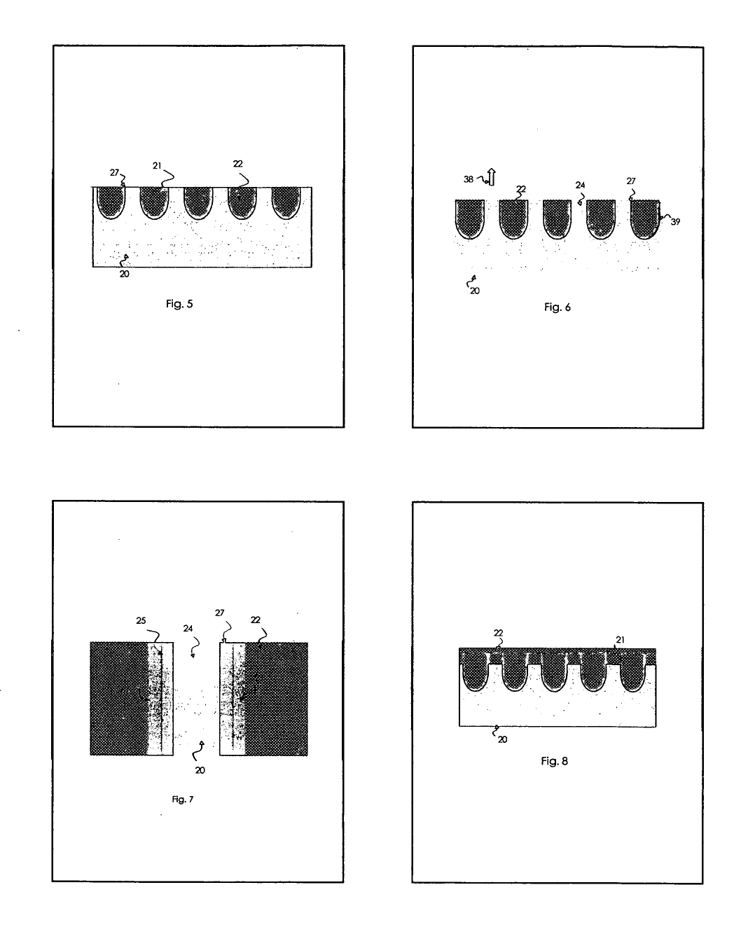

The substrate with the active photovoltaic film, FIG. 4, is now filled with a conductive material (22), which is used to form a conductor. The conductor (22) is needed to carry away the electric current generated by the photovoltaic action. Other methods of forming the conductor are possible, such as, deposition of a metal by sputtering, electroplating, or another equivalent deposition method. If one of these deposition methods is used, filling the trenches with a material may be necessary to add strength to the structure. The inner surface of the conductive material is mirror-like, so that it will efficiently reflect any sunlight that passes through the active film without being absorbed (26).

Next, the surface is ground with a grinding machine, or equivalent process, to expose the edge of the active film, FIG. 5 (27).

At this point, FIG. 6, the exposed substrate is etched to form channels (24), and the etch byproducts (38) are removed. If a barrier film (39) is not used, the etch chemistry must be selective, so that the active film (21) remains intact.

FIG. 7 summarizes the form of the structure to this point. It has a conductive material (22), an active film (21), an active junction where the photovoltaic phenomena will occur (25), an edge of the active film (27), an empty space (24), the transparent substrate (20), and a reflective surface (26).

At this point, FIG. 8, coat the surface with conductive material (22), so that the empty space (24) is filled and contact to the active film (21) can be made. Other methods of forming the conductor are possible, such as, deposition of metal by sputtering, electroplating, or equivalent.

In FIG. 9, grind the surface to remove excess material and expose a new edge of the active junction (41). This grinding step should include a chemical compound, Chemical Mechanical Polishing (CMP), to remove grinding damage to the edge of the active film. A wet or plasma etching step following normal grinding may achieve the same result.

Deposit a film, FIG. 10 (28), to passivate the exposed edge of the active film. Since the same film may be used as the anti-reflective film on the other side of the substrate, the deposition of the film in the two sides may be combined in a single step. FIG. 10 also shows the maximum distance that the electric current must flow in the active film to reach the conductor (34). This is much shorter when compared to a flat thin film photovoltaic solar cell, where the contact is usually made to the edge.

FIG. 11 summarizes the final structure. It has a conductive material to form the conductor on one side of the active film (29), a conductor material to form the conductor on the other side of the active film (30), an active junction where the photovoltaic phenomena occurs (25), a passivation layer (28) to protect the active junction (41), and a transparent substrate (2). Note that because of the grinding process conductor (22) has been split into (29) and (30).

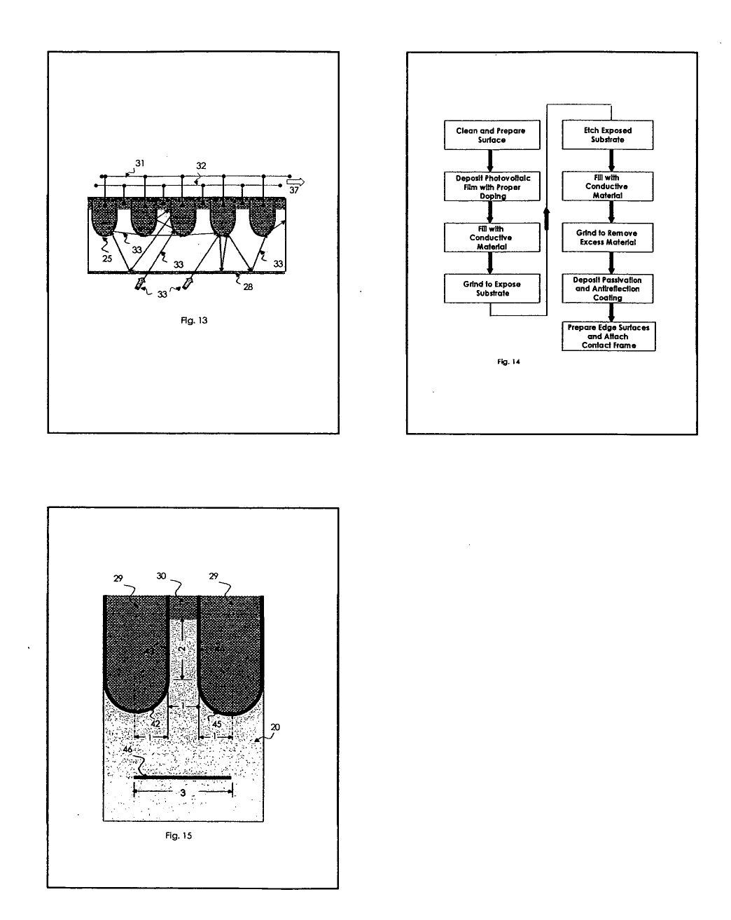

In FIG. 12, contact frames, (31) and (32), are attached to the two ends of the conductors, (29) and (30), enabling electric output. Attachment of the frames should be made by soldering or equivalent method.

At this point the solar cell is complete, FIG. 13. Sunlight (33) enters the substrate through the antireflective coating, and remains trapped inside the substrate until it is absorbed by the active junction (25) or lost by heat or incomplete reflections. An electric potential is generated between frame wires (31) and (32) and electric current can now flow (37) to a load.

The process flow for manufacturing the complete photovoltaic cell is shown in FIG. 14. Intermediate cleaning and handling steps are not shown.

In FIG. 15, notice that the active surface area is increased from a referenced flat surface (46). For each U-shaped surface, assume that the active area divided by the equivalent linear surface of 3 units is [(22)+(43)+(44)+(40)]/3=[π/2+2+2+π/2]/3=2.37 times greater than an equivalent linear flat surface (46). Thus, the photovoltaic efficiency is improved by at least 237% when compared to a flat photovoltaic panel. This assumes equivalent losses in the flat cell and in the U-shaped cell and the same depth dimension.

What is claimed is:

1. A method of fabricating a photovoltaic solar cell, whereby the active surface area of a thin film is increased by depositing the film on U-shaped trenches on a transparent substrate.

2. A solar cell of claim 1, whereby contact to the two sides of the active film is made from the same side of the cell.

3. A solar cell of claim 1 whereby the efficiency compared to a flat solar cell is increased, because of increased active surface area.

4. A solar cell of claim 1 whereby the efficiency is increased because of the short distance current must flow in the active film between the generation point to the output conductor.

5. A solar cell of claim 1 having large dimensions.

6. A solar cell of claim 1 having passivation.

7. A solar cell of claim 1 having an antireflection coating.

8. A solar cell of claim 1 having the possibility of simultaneous deposition of antireflective and passivation coating.

9. A solar cell of claim 1 having a simple contact frame for the electrical output.

10. A solar cell of claim 1 having a reflective conductive material that favors multiple light passes.

11. A solar cell of claim 1 whereby the active film may be made of any photovoltaic material that has the electrical output obtained from the two sides of the film.

12. A solar cell of claim 1, whereby the active film may be made by more than two layers.

13. A solar cell of claim 1 whereby the U-shaped trenches may have different shapes achieving the same results of increased active surface area and contactability.

14. A solar cell of claim 1, whereby other films to improve conductivity may be deposited prior to the deposition of the active film.
